(19) United States
(12) Patent Application Publication
(10) Pub. No.: US 2020/0295282 A1
(43) Pub. Date: Sep. 17, 2020

(54) DISPLAY DEVICE AND MANUFACTURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Ming XIANG, Wuhan, Hubei (CN)

(21) Appl. No.: 16/472,893

(22) PCT Filed: Feb. 26, 2019
(86) PCT No.: PCT/CN2019/076146

§ 371 Date: Jun. 23, 2019

(30) Foreign Application Priority Data
Dec. 14, 2018 (CN) 201811534927.8

(51) Int. Cl. H01L 51/00; H01L 51/56

(52) U.S. Cl. CPC H01L 51/0097; H01L 2251/5338; H01L 51/56

(57) ABSTRACT

A display device and a manufacturing method thereof are provided. The display device includes a first flexible substrate layer, at least one buffer layer, and a second flexible substrate layer, wherein the second flexible substrate layer is formed on the buffer layer, and the buffer layer is formed on the first flexible substrate layer; a bending region of the buffer layer is formed with a patterned pattern such that the first flexible substrate layer is attached to the second flexible substrate layer through the pattern.

### FIELD OF INVENTION

The present disclosure relates to a display device, and in particular to a display device with an active matrix organic light emitting diode.

### BACKGROUND OF INVENTION

Organic light emitting diode (OLED) displays are self-luminous displays. According to the driving method, they can be divided into passive matrix driving organic light emitting diode (PMOLED) displays and active matrix driving organic light emitting diode (AMOLED) displays. AMOLED displays have advantages, such as low manufacturing cost, fast response times, power savings, DC drive for portable devices, and a wide operating temperature range. Therefore, more and more AMOLED displays are used in a variety of displays with high performance.

Further, in the display device of the AMOLED display, a first flexible substrate layer, a buffer layer and a second flexible substrate layer are disposed on a glass substrate. Then the glass substrate peeled by laser, and a back plane is attached, wherein the first flexible substrate layer and the second flexible substrate layer can be an organic polyimide film, and the buffer layer is an inorganic layer (SiOx).

However, for display devices with a two-layer organic polyimide film, the adhesion ability of the organic polyimide film to the inorganic layer is limited. A neutral axis of a bending region of the display device is disposed on a metal axis layer that is susceptible to bending. Therefore, separation of the organic polyimide film from the inorganic layer is apt to occur at a starting position, an intermediate position, and an ending position of the bending region.

As a result, it is necessary to provide a display device and a manufacturing method of the display device to solve the problems existing in the conventional technologies, as described above.

### SUMMARY OF THE INVENTION

An object of the present disclosure is to provide a display device and a manufacturing method thereof, wherein a risk of a first flexible substrate layer and a second flexible substrate layer being separated from a buffer layer is reduced by forming the pattern in a bending region of the buffer layer.

To achieve the above objects, the present disclosure provides a display device, and the display device comprises a first flexible substrate layer, at least one buffer layer, and a second flexible substrate layer. The second flexible substrate layer is formed on the buffer layer, and the buffer layer is formed on the first flexible substrate layer; a bending region of the buffer layer is formed with a patterned pattern such that the first flexible substrate layer is attached to the second flexible substrate layer through the pattern, and a material of the first flexible substrate layer and the second flexible substrate layer is polyimide.

In one embodiment of the present disclosure, the pattern is formed with a plurality of holes.

In one embodiment of the present disclosure, the holes are circular, vertical elliptical, transversely elliptical, square, equilateral, or inverted triangles.

In one embodiment of the present disclosure, the bending region of the buffer layer includes two corresponding sides, and a diameter of the hole located at two corresponding sides of the bending region is greater than a diameter of the hole located at a middle of the bending region.

In one embodiment of the present disclosure, the display device further includes a first back plane and a second back plane, and the first flexible substrate layer is disposed on the first back plane and the second back plane; a bending space is formed between the first back plane and the second back plane, and the bending region of the buffer layer corresponds to the bending space.

In one embodiment of the present disclosure, an inner surface of the second flexible substrate layer is attached to an outer surface of the buffer layer, an inner surface of the buffer layer is attached to an outer surface of the first flexible substrate layer, and the first back plane and the second back plane are attached to an inner surface of the first flexible substrate layer.

In one embodiment of the present disclosure, the display device further includes a panel, and an inner surface of the panel is attached to an outer surface of the second flexible substrate layer.

In one embodiment of the present disclosure, the display device further includes a stiffener, and the stiffener is disposed between the first back plane and the second back plane.

To achieve the above objects, the present disclosure provides a manufacturing method of a display device, and the manufacturing method comprises a first flexible substrate layer forming step, a buffer layer forming step, a second flexible substrate layer forming step, and a bending step. The first flexible substrate layer forming step is to form a first flexible substrate layer; the buffer layer forming step is to forme a buffer layer on the first flexible substrate later, wherein a bending region of the buffer layer is formed with a patterned pattern; the second flexible substrate layer forming step is to form a second flexible substrate layer on the buffer layer; the bending step is to bend the bending region of the buffer layer such that the first flexible substrate layer is attached to the second flexible substrate layer through the pattern.

In one embodiment of the present disclosure, in the buffer layer forming step, the pattern is formed with a plurality of holes, and the holes are circular, vertical elliptical, transversely elliptical, square, equilateral, or inverted triangles.

To achieve the above objects, the present disclosure provides a display device, and the display device comprises a first flexible substrate layer, at least one buffer layer, and a second flexible substrate layer. The the second flexible substrate layer is formed on the buffer layer, and the buffer layer is formed on the first flexible substrate layer; a bending region of the buffer layer is formed with a patterned pattern such that the first flexible substrate layer is attached to the second flexible substrate layer through the pattern.

In one embodiment of the present disclosure, the pattern is formed with a plurality of holes.

In one embodiment of the present disclosure, the holes are circular, vertical elliptical, transversely elliptical, square, equilateral, or inverted triangles.

In one embodiment of the present disclosure, the bending region of the buffer layer includes two corresponding sides, and a diameter of the hole located at two corresponding sides of the bending region is greater than a diameter of the hole located at a middle of the bending region.

In one embodiment of the present disclosure, the display device further includes a first back plane and a second back plane, and the first flexible substrate layer is disposed on the first back plane and the second back plane; a bending space is formed between the first back plane and the second back plane, and the bending region of the buffer layer corresponds to the bending space.

In one embodiment of the present disclosure, an inner surface of the second flexible substrate layer is attached to an outer surface of the buffer layer, an inner surface of the buffer layer is attached to an outer surface of the first flexible substrate layer, and the first back plane and the second back plane are attached to an inner surface of the first flexible substrate layer.

In one embodiment of the present disclosure, the display device further includes a panel, and an inner surface of the panel is attached to an outer surface of the second flexible substrate layer.

In one embodiment of the present disclosure, the display device further includes a stiffener, and the stiffener is disposed between the first back plane and the second back plane.

As described above, forming the pattern in the buffer layer, the first flexible substrate layer is attached to the second flexible substrate layer through the pattern. The contact area between the first flexible substrate layer and the second flexible substrate layer can be increased. In the bending process of the display device, the risk of the first flexible substrate layer and the second flexible substrate layer being separated from the buffer layer is reduced.

### DESCRIPTION OF DRAWINGS

In order to more clearly illustrate the embodiments or prior art technical solutions embodiment of the present disclosure, will implement the following figures for the cases described in prior art or require the use of a simple introduction. Obviously, the following description of the drawings are only some of those of ordinary skill in terms of creative effort without precondition, you can also obtain other drawings based on these drawings embodiments of the present disclosure.

FIG. 1 is a cross-sectional view of a display device according to a preferred embodiment of the present disclosure.

FIG. 2 is a top view of a buffer layer of the display device according to a preferred embodiment of the present disclosure.

FIG. 3 is a top view of another aspect of the buffer layer of a display device according to a preferred embodiment of the present disclosure.

FIG. 4 is a top view of still another aspect of the buffer layer of a display device according to a preferred embodiment of the present disclosure.

FIG. 5 is a flowchart of a manufacturing method of a display device according to a preferred embodiment of the present disclosure.

FIG. 6 is a schematic view of a first flexible substrate layer forming step of the manufacturing method of a display device according to a preferred embodiment of the present disclosure.

FIG. 7 is a schematic view of a buffer layer forming step of the manufacturing method of a display device according to a preferred embodiment of the present disclosure.

FIG. 8 is a schematic view of a second flexible substrate layer forming step of the manufacturing method of a display device according to a preferred embodiment of the present disclosure.

### DETAILED DESCRIPTION OF PREFERRED EMBODIMENTS

Structure and technical means adopted by the present disclosure to achieve the above and other objects can be best understood by referring to the following detailed description of the preferred embodiments and the accompanying drawings. Furthermore, directional terms described by the present disclosure, such as upper, lower, front, back, left, right, inner, outer, side, longitudinal/vertical, transverse/horizontal, etc., are only directions by referring to the accompanying drawings, and thus the used directional terms are used to describe and understand the present disclosure, but the present disclosure is not limited thereto.

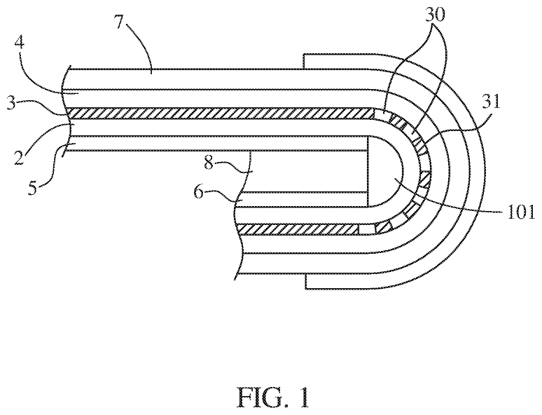

Referring to FIG. 1, a view of a display device according to a preferred embodiment of the present disclosure is illustrated. The display device includes a first flexible substrate layer 2, a buffer layer 3, a second flexible substrate layer 4, a first back plane 5, and a second back plane 6. The detailed structure of each component, assembly relationships, and principles of operation in the present invention will be described in detail hereinafter.

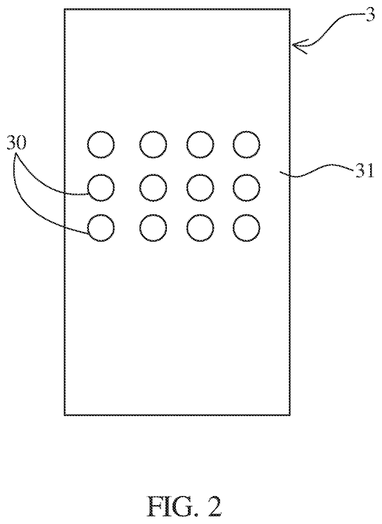

Referring to FIG. 1, the second flexible substrate layer 4 is formed on the buffer layer 3, the buffer layer 3 is formed on the first flexible substrate layer 2, and the first flexible substrate layer 2 is formed on the first back plane 5 and the second back plane 6. A bending space 101 is formed between the first back plane 5 and the second back plane 6, and a bending region of the buffer layer 3 is formed with a patterned pattern such that the first flexible substrate layer 2 is attached to the second flexible substrate layer 4 through the pattern. In the embodiment, the pattern is formed with a plurality of holes 30, and the holes 30 are disposed on the bending region 31 of the buffer layer 3 (shown in FIG. 2), wherein the holes 30 correspond to the bending space 101.

Referring to FIG. 1, in the embodiment, an inner surface of the second flexible substrate layer 4 is attached to an outer surface of the buffer layer 3, an inner surface of the buffer layer 3 is attached to an outer surface of the first flexible substrate layer 2, and the first back plane 5 and the second back plane 6 are attached to an inner surface of the first flexible substrate layer 2.

Referring to FIG. 1, the display device further includes a panel 7 and a stiffener 8, wherein an inner surface of the panel 7 is attached to an outer surface of the second flexible substrate layer 4, and the panel 7 is an active matrix organic light emitting diode (AMOLED) screen in the embodiment. In other embodiment, the second flexible substrate layer 4 and the panel 7 can be replaced with a structure of a relevant layer of a liquid crystal display, which is not limited by this embodiment. In addition, the stiffener 8 is disposed between the first back plane 5 and the second back plane 6, and the stiffener 8 is configured to prevent a bending angle between the first back plane 5 and the second back plane 6 from being too small to avoid metal wire breakage of the panel 7.

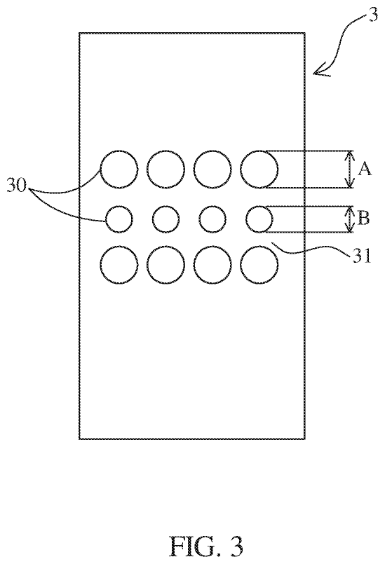

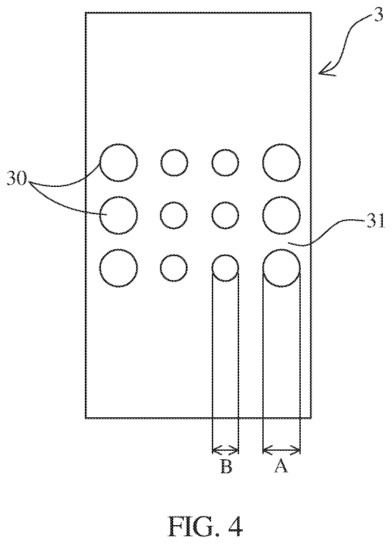

Referring to FIGS. 1 and 2, in the embodiment, the holes 30 are circular, vertical elliptical, transversely elliptical, square, equilateral, or inverted triangles (not shown). In the other embodiment, the bending region 31 of the buffer layer 3 includes two corresponding sides, and a diameter A of the hole 30 located at two corresponding sides of the bending region 31 is greater than a diameter B of the hole 30 located at a middle of the bending region 31 (shown in FIG. 3 or FIG. 4). In addition, a material of the buffer layer 3 is silicon oxide, and a material of the first flexible substrate layer and the second flexible substrate layer is polyimide.

As described above, forming a plurality of holes 30 of the pattern in the buffer layer 3, the first flexible substrate layer 2 is attached to the second flexible substrate layer 4 through the pattern. The contact area between the first flexible substrate layer 2 and the second flexible substrate layer 4 can be increased. Simultaneously, reducing the contact area of the first flexible substrate layer 2 and the buffer layer 3 and the contact area of the second flexible substrate layer 4 and the buffer layer 3. In the bending process of the display device, the risk of the first flexible substrate layer 2 and the second flexible substrate layer 4 being separated from the buffer layer 3 is reduced. In addition, in the bending process, the design of the hole 30 with the diameter A and the hole 30 with the diameter B can further improve the reliability of the bending region 31 when bending.

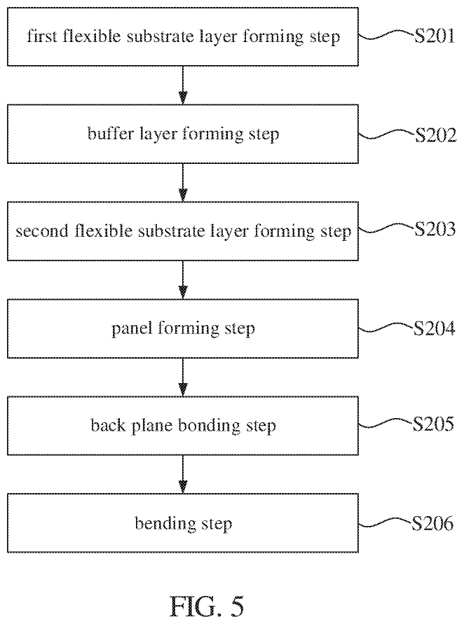

Referring to FIG. 5 in conjunction with FIG. 6, a flowchart of a manufacturing method of a display device according to a preferred embodiment of the present disclosure is illustrated, wherein the manufacturing method includes a first flexible substrate layer forming step S201, a buffer layer forming step S202, a second flexible substrate layer forming step S203, a panel forming step S204, a back plane bonding step S205, and a bending step S206. The detailed principles of operation for the present invention will be described in detail hereinafter.

Referring to FIG. 5 in conjunction with FIG. 6, in the first flexible substrate layer forming step S201, a first flexible substrate layer 2 is formed on a glass substrate 102. In the embodiment, a material of the first flexible substrate layer 2 is polyimide.

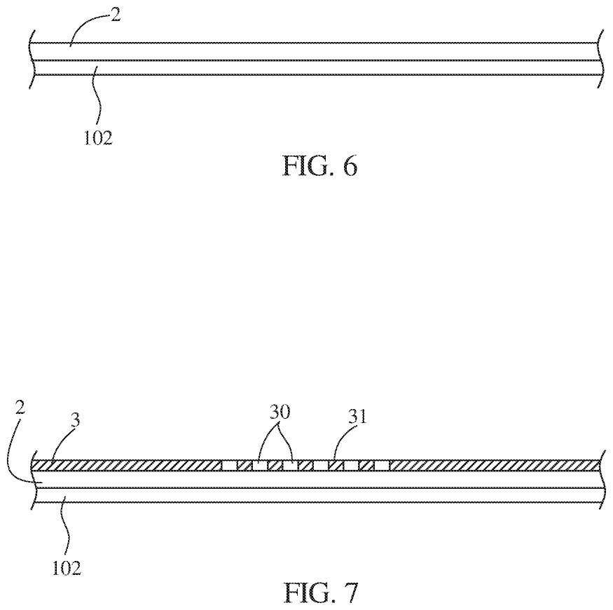

Referring to FIG. 5 in conjunction with FIG. 7, in the buffer layer forming step S202, the buffer layer 3 is formed on the first flexible substrate layer 2, and a bending region 31 of the buffer layer 3 is formed with a patterned pattern. In the embodiment, the pattern is formed with a plurality of holes 30, and the holes 30 are disposed on the bending region 31 of the buffer layer 3, wherein a material of the buffer layer 3 is silicon oxide.

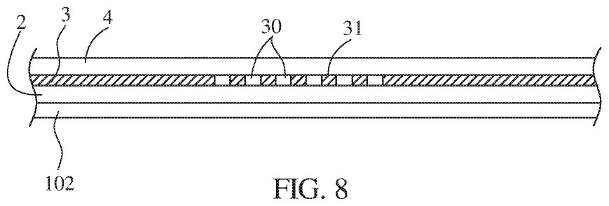

Referring to FIG. 5 in conjunction with FIG. 8, in the second flexible substrate layer forming step S203, the second flexible substrate layer 4 is formed on the buffer layer 3. In the embodiment, a material of the second flexible substrate layer 4 is polyimide.

Referring to FIG. 5 in conjunction with FIG. 1, in the panel forming step S204, a panel 7 is formed on the second flexible substrate layer 4. In the embodiment, the panel 7 is an active matrix organic light emitting diode (AMOLED) screen, wherein the manufacturing process of the panel 7 is prior art, and thus will not be further described.

Referring to FIG. 5 in conjunction with FIG. 1, in the back plane bonding step S205, the glass substrate 102 is removed. In the embodiment, the glass substrate 102 is peeled off from the first flexible substrate layer 2 by a laser lift off technique (LLO), and then a first back plane 5 and a second back plane 6 are attached to an inner surface of the first flexible substrate layer 2.

Referring to FIG. 5 in conjunction with FIG. 1, in the bending step S206, the second back plate 6 is bent toward the first back plate 5, and the bending region 31 of the buffer layer 3 is bent simultaneously such that the first flexible substrate layer 2 is attached to the second flexible substrate layer 4 by the pattern. A stiffener 8 is then disposed between the first back plate 5 and the second back plate 6 to form the display device. In the embodiment, a bending space 101 is formed between the first back plate 5 and the second back plate 6, and the holes 30 correspond to the bending space 101.

As described above, forming a plurality of holes 30 of the pattern in the buffer layer 3, the first flexible substrate layer 2 is attached to the second flexible substrate layer 4 through the pattern. The contact area between the first flexible substrate layer 2 and the second flexible substrate layer 4 can be increased. Simultaneously, reducing the contact area of the first flexible substrate layer 2 and the buffer layer 3 and the contact area of the second flexible substrate layer 4 and the buffer layer 3. In the bending process of the display device, the risk of the first flexible substrate layer 2 and the second flexible substrate layer 4 being separated from the buffer layer 3 is reduced. In addition, in the bending process, the design of the hole 30 with the diameter A and the hole 30 with the diameter B can further improve the reliability of the bending region 31 when bending.

The present disclosure has been described with preferred embodiments thereof and it is understood that many changes and modifications to the described embodiments can be carried out without departing from the scope and the spirit of the disclosure that is intended to be limited only by the appended claims.

What is claimed is:

1. A display device, comprising:
a first flexible substrate layer, at least one buffer layer, and a second flexible substrate layer;
wherein the second flexible substrate layer is formed on the buffer layer, and the buffer layer is formed on the first flexible substrate layer; a bending region of the buffer layer is formed with a patterned pattern such that the first flexible substrate layer is attached to the second flexible substrate layer through the pattern, and a material of the first flexible substrate layer and the second flexible substrate layer is polyimide.

2. The display device according to claim 1, wherein the pattern is formed with a plurality of holes.

3. The display device according to claim 2, wherein the holes are circular, vertical elliptical, transversely elliptical, square, equilateral, or inverted triangles.

4. The display device according to claim 2, wherein the bending region of the buffer layer includes two corresponding sides, and a diameter of the hole located at two corresponding sides of the bending region is greater than a diameter of the hole located at a middle of the bending region.

5. The display device according to claim 1, wherein the display device further includes a first back plane and a second back plane, and the first flexible substrate layer is disposed on the first back plane and the second back plane; a bending space is formed between the first back plane and the second back plane, and the bending region of the buffer layer corresponds to the bending space.

6. The display device according to claim 5, wherein an inner surface of the second flexible substrate layer is attached to an outer surface of the buffer layer, an inner surface of the buffer layer is attached to an outer surface of the first flexible substrate layer, and the first back plane and the second back plane are attached to an inner surface of the first flexible substrate layer.

7. The display device according to claim 6, wherein the display device further includes a panel, and an inner surface of the panel is attached to an outer surface of the second flexible substrate layer.

8. The display device according to claim 7, wherein the display device further includes a stiffener, and the stiffener is disposed between the first back plane and the second back plane.

9. A manufacturing method of a display device, comprising steps of:
a first flexible substrate layer forming step for forming a first flexible substrate layer;
a buffer layer forming step for forming a buffer layer on the first flexible substrate later, wherein a bending region of the buffer layer is formed with a patterned pattern;
a second flexible substrate layer forming step for forming a second flexible substrate layer on the buffer layer; and
a bending step for bending the bending region of the buffer layer such that the first flexible substrate layer is attached to the second flexible substrate layer through the pattern.

10. The manufacturing method according to claim 9, wherein in the buffer layer forming step, the pattern is formed with a plurality of holes, and the holes are circular, vertical elliptical, transversely elliptical, square, equilateral, or inverted triangles.

11. A display device, comprising:
a first flexible substrate layer, at least one buffer layer, and a second flexible substrate layer;
wherein the second flexible substrate layer is formed on the buffer layer, and the buffer layer is formed on the first flexible substrate layer; a bending region of the buffer layer is formed with a patterned pattern such that the first flexible substrate layer is attached to the second flexible substrate layer through the pattern.

12. The display device according to claim 11, wherein the pattern is formed with a plurality of holes.

13. The display device according to claim 12, wherein the holes are circular, vertical elliptical, transversely elliptical, square, equilateral, or inverted triangles.

14. The display device according to claim 12, wherein the bending region of the buffer layer includes two corresponding sides, and a diameter of the hole located at two corresponding sides of the bending region is greater than a diameter of the hole located at a middle of the bending region.

15. The display device according to claim 11, wherein the display device further includes a first back plane and a second back plane, and the first flexible substrate layer is disposed on the first back plane and the second back plane; a bending space is formed between the first back plane and the second back plane, and the bending region of the buffer layer corresponds to the bending space.

16. The display device according to claim 15, wherein an inner surface of the second flexible substrate layer is attached to an outer surface of the buffer layer, an inner surface of the buffer layer is attached to an outer surface of the first flexible substrate layer, and the first back plane and the second back plane are attached to an inner surface of the first flexible substrate layer.

17. The display device according to claim 16, wherein the display device further includes a panel, and an inner surface of the panel is attached to an outer surface of the second flexible substrate layer.

18. The display device according to claim 17, wherein the display device further includes a stiffener, and the stiffener is disposed between the first back plane and the second back plane.
